(19) United States
(12) Patent Application Publication
(10) Pub. No.: US 2026/0231425 A1
(43) Pub. Date: Aug. 6, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Dae Sung EOM, Gyeonggi-do (KR)

(21) Appl. No.: 19/192,369

(22) Filed: Apr. 29, 2025

(30) Foreign Application Priority Data
Jan. 31, 2025 (KR) 10-2025-0012428

(51) Int. Cl. H10B 43/40; H10B 41/10; H10B 41/27; H10B 41/41; H10B 43/10; H10B 43/27

(52) U.S. Cl. CPC H10B 43/40; H10B 41/10; H10B 41/27; H10B 41/41; H10B 43/10; H10B 43/27

(57) ABSTRACT

A semiconductor device is provided. The semiconductor device includes a substrate including a cell region and a peripheral circuit region, a gate structure including conductive layers and being located in the cell region, an electrode stack including electrode layers and being located in the peripheral circuit region, a slit structure extending through the gate structure, first electrode structures extending through the electrode stack and being electrically connected to the electrode layers, a second electrode structure extending through the electrode stack and being located at a level corresponding to the slit structure, and an insulating spacer surrounding the second electrode structure.

### CROSS-REFERENCE TO RELATED APPLICATION

This application claims priority under 35 U.S.C. §119 to Korean Patent Application No. 10-2025-0012428 filed on January 31, 2025, which is incorporated herein by reference in its entirety.

### BACKGROUND

### Technical Field

The present disclosure relates to an electronic device and a method of manufacturing the electronic device, and more particularly, to a semiconductor device and a method of manufacturing the semiconductor device.

### Related Art

An integration degree of a semiconductor device is mainly determined by an area occupied by a unit memory cell. Recently, as improvement in an integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include a substrate including a cell region and a peripheral circuit region, a gate structure including conductive layers and being located in the cell region, an electrode stack including electrode layers and being located in the peripheral circuit region, a slit structure extending through the gate structure, first electrode structures extending through the electrode stack and being electrically connected to the electrode layers, a second electrode structure extending through the electrode stack and being located at a level corresponding to the slit structure, and an insulating spacer surrounding the second electrode structure.

According to an embodiment of the present disclosure, a semiconductor device may include an electrode stack including electrode layers, a first electrode structure extending through the electrode stack and being electrically connected to the electrode layers, a second electrode structure extending through the electrode stack and including a material different from a material of the first electrode structure, and an insulating spacer surrounding the second electrode structure.

According to an embodiment of the present disclosure, a method of manufacturing a semiconductor device may include alternately stacking first material layers and second material layers on a substrate to form a stack, the substrate including a cell region and a peripheral circuit region, forming electrode holes penetrating through the stack in the peripheral circuit region, forming electrode sacrificial layers in the electrode holes, forming a first slit penetrating through the stack in the cell region, forming a second slit penetrating through the stack in the peripheral circuit region, forming an insulating spacer in the second slit, forming a second electrode structure inside the insulating spacer, forming first contact holes exposing the second material layers, respectively, while opening the electrode holes by removing the electrode sacrificial layers, and forming first electrode structures in the electrode holes.

### BRIEF DESCRIPTION OF THE DRAWINGS

FIGS. 1A to 1C are views illustrating a semiconductor device according to an embodiment of the present disclosure.

FIGS. 2A to 2C are views illustrating a semiconductor device according to an embodiment of the present disclosure.

FIGS. 3A and 3B are views illustrating a semiconductor device according to an embodiment of the present disclosure.

FIGS. 4A, 4B, 4C, 5A, 5B, 5C, 6A, 6B, 6C, 7A, 7B, and 7C are views illustrating a method of manufacturing a semiconductor device according to an embodiment of the present disclosure.

FIGS. 8A, 8B, 9A, 9B, 10A, and 10B are views illustrating a method of manufacturing a semiconductor device according to an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and scope of the present disclosure.

It will be understood that, although the terms "first", "second", "third", and so on may be used herein to describe various elements, these elements are not limited by these terms. These terms are used to distinguish one element from another element. Thus, a first element described below could also be termed as a second or third element without departing from the principles and scope of the present disclosure.

It will be further understood that when an element is referred to as being "connected to", or "coupled to" another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being "between" two elements, it may be the only element between the two elements, or one or more intervening elements may also be present.

When a first element is referred to as being "over" a second element, it not only refers to a case where the first element is formed directly on the second element but also a case where a third element exists between the first element and the second element. When a first element is referred to as being "on" a second element, it refers to a case where the first element is formed directly or indirectly on the second element or the substrate.

As used herein, a "layer" refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

As used herein, singular forms are intended to include the plural forms as well, unless the context clearly indicates otherwise.

An embodiment of the present disclosure provides a semiconductor device and a method of manufacturing the semiconductor device having a stable structure and an improved characteristic.

According to the present technology, a semiconductor device having a stable structure and improved reliability may be provided.

Hereinafter, embodiments according to the technical spirit of the present disclosure are described with reference to the accompanying drawings.

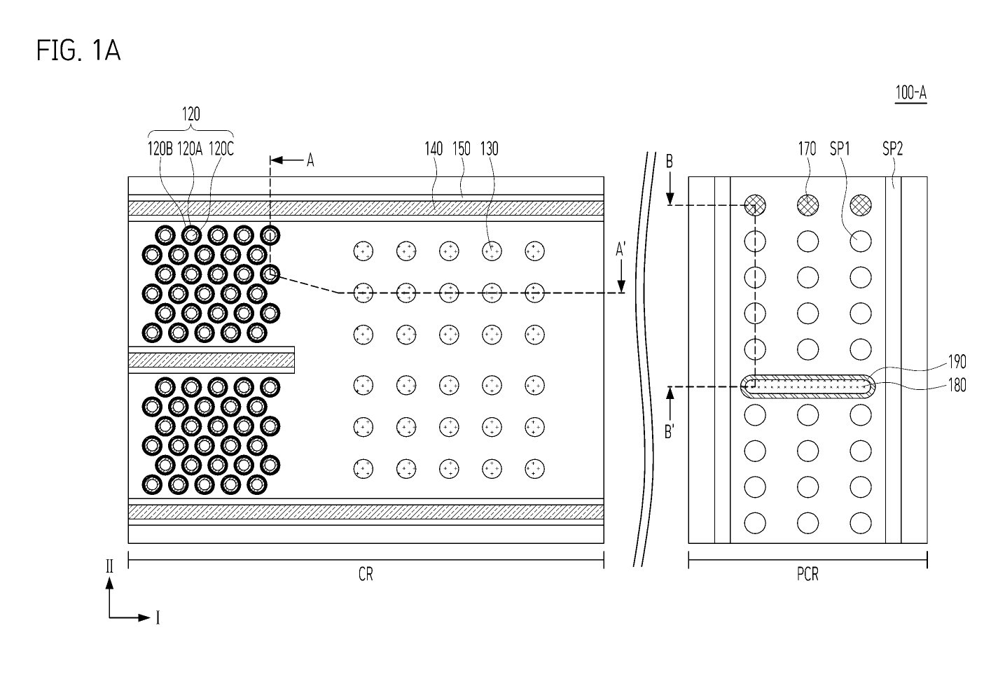

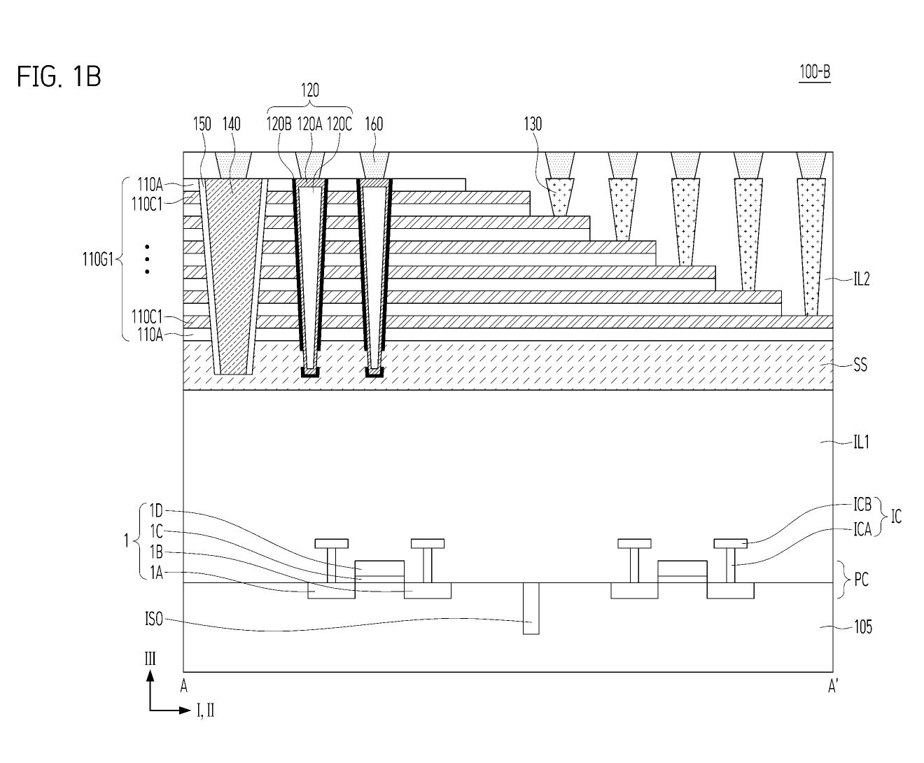

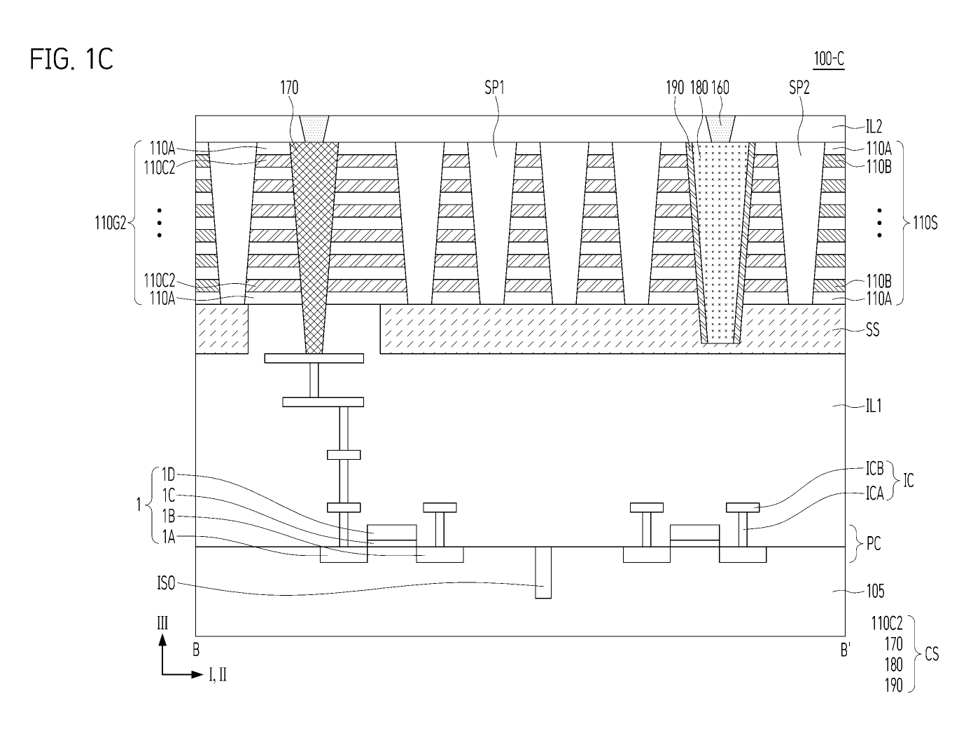

FIGS. 1A to 1C are views illustrating a semiconductor device 100 according to an embodiment of the present disclosure. FIG. 1A is a plan view (100-A), FIG. 1B is an A-A' cross-sectional view of FIG. 1A (100-B), and FIG. 1C is a B-B' cross-sectional view of FIG. 1A (100-C).

Referring to FIGS. 1A to 1C, the semiconductor device 100 may include a substrate 105, a gate structure 110G1, an electrode stack 110G2, a residual stack 110S, channel structures 120, first contact vias 130, a slit structure 140, a slit spacer 150, second contact vias 160, first electrode structures 170, a second electrode structure 180, and an insulating spacer 190. The semiconductor device 100 may further include a peripheral circuit PC, a source structure SS, first supports SP1, second supports SP2, an interconnection structure IC, a first interlayer insulating layer IL1, a second interlayer insulating layer IL2, and an element isolation layer ISO.

The substrate 105 may include a cell region (CR and a peripheral circuit region PCR. The cell region CR may be spaced apart from the peripheral circuit region PCR in a first direction I. However, the cell region CR is not limited thereto, and may be spaced apart from the peripheral circuit region PCR in a second direction II intersecting with the first direction I. The cell region CR may be a region where memory cells are located. The peripheral circuit region PCR may be a region where a peripheral circuit (PC) such as a transistor 1 is located.

The peripheral circuit PC may be located on the substrate 105. For example, the peripheral circuit PC may be located in the peripheral circuit region PCR. However, the peripheral circuit PC is not limited thereto, and the peripheral circuit PC may be located in the cell region CR and the peripheral circuit region PCR. The peripheral circuit PC may include the transistor 1, a capacitor, and similar electronic components. The transistor 1 may include junctions 1A and 1B, a gate electrode 1D, and a gate insulating layer 1C. Here, the gate insulating layer 1C may be located between the gate electrode 1D and the substrate 105. The element isolation layer ISO may be located in the substrate 105, an active region may be defined by the element isolation layer ISO, and the transistor 1 may be located in the active region.

The interconnection structure IC may be connected to the peripheral circuit PC. For example, at least one of vias ICA (note that although vias ICA is illustrated as a single instance for clarity of illustration, there may be several) may be connected to the transistor 1. At least one of the vias ICA may interconnect lines ICB (note that although interconnect lines ICB is illustrated as a single instance for clarity of illustration, there may be several). The lines ICB may interconnect the vias ICA. The interconnection structure IC may include a conductive material such as tungsten. The first interlayer insulating layer IL1 may include an insulating material such as an oxide.

The gate structure 110G1 may be located in the cell region CR. The gate structure 110G1 may include first insulating layers 110A and conductive layers 110C1 alternately stacked. The conductive layers 110C1 may be a gate line such as a source selection line, a word line, and a drain selection line. A source selection transistor, a memory cell, or a drain selection transistor may be located in a region where the channel structures 120 and the conductive layers 110C1 cross. For example, at least one source selection transistor, a plurality of memory cells, and at least one drain selection transistor stacked along the channel structures 120 may configure one memory string. The conductive layers 110C1 may include a conductive material such as tungsten, molybdenum, or polysilicon.

The electrode stack 110G2 may be located in the peripheral circuit region PCR. The electrode stack 110G2 may include first insulating layers 110A and electrode layers 110C2 alternately stacked. Here, the electrode layers 110C2 may be located at a level corresponding to the conductive layers 110C1. The electrode layers 110C2 may include a conductive material such as tungsten, molybdenum, or polysilicon.

The residual stack 110S may be located in the peripheral circuit region PCR. However, the residual stack 110S is not limited thereto, and the residual stack 110S1 may extend from the peripheral circuit region PCR to the cell region CR. The residual stack 110S may include first insulating layers 110A and second insulating layers 110B alternately stacked. Here, the second insulating layers 110B may be located at a level corresponding to the conductive layers 110C1 and the electrode layers 110C2. The first insulating layers 110A may include an insulating material such as an oxide. The second insulating layers 110B may include a sacrificial material such as a nitride.

The source structure SS may be located on the peripheral circuit PC. For example, the source structure SS may be located between the peripheral circuit PC and the gate structure 110G1 and between the peripheral circuit PC and the electrode stack 110G2. In other words, the source structure SS may extend from the peripheral circuit region PCR to the cell region CR. The source structure SS may be a single layer or multiple layers. The source structure SS may include polysilicon and materials that perform a similar function.

The channel structures 120 may extend into the source structure SS through the gate structure 110G1. Each of the channel structures 120 may include a channel layer 120A and a memory layer 120B surrounding the channel layer 120A. Each of the channel structures 120 may include an insulating core 120C in the channel layer 120A. Here, the channel layer 120A may be connected to the source structure SS.

Each of the first contact vias 130 may be connected to one of the conductive layers 110C1 of the gate structure 110G1. For example, the first contact vias 130 may be connected to the conductive layers 110C1 of the gate structure 110G1, respectively. The first contact vias 130 may extend through the second interlayer insulating layer IL2 and may be respectively connected to an upper surface of the conductive layers 110C1. Here, the second interlayer insulating layer IL2 may be located on the gate structure 110G1. The first contact vias 130 may have different heights. The first contact vias 130 may include a conductive material such as tungsten, and the second interlayer insulating layer IL2 may include an insulating material such as an oxide.

For reference, although this figure illustrates an instance in which the gate structure 110G1 includes a step structure, the gate structure 110G1 may not include a step structure. In that instance, the first contact vias 130 may extend through the gate structure 110G1 and may be respectively connected to the conductive layers 110C1.

The slit structure 140 may extend through the gate structure 110G1. For example, the slit structure 140 may extend into the source structure SS through the gate structure 110G1. Here, the slit structure 140 may be a source contact structure. The slit structure 140 may have a line shape extending in the first direction I. The slit structure 140 may include at least one of a semiconductor material or a conductive material. For example, the slit structure 140 may include polysilicon.

The slit spacer 150 may surround a sidewall of the slit structure 140. The slit spacer 150 may prevent the slit structure 140 and the conductive layers 110C1 from being electrically connected. The slit spacer 150 may include an insulating material such as an oxide.

The second contact vias 160 may be located in the cell region CR and the peripheral circuit region PCR. The second contact vias 160 may be connected to at least one of the slit structure 140, the channel structures 120, or the first contact vias 130. The second contact vias 160 may include a conductive material such as tungsten.

The first supports SP1 may be located in the peripheral circuit region PCR. The first supports SP1 may extend through the electrode stack 110G2. The first supports SP1 may be arranged in the first direction I and the second direction II. The first supports SP1 may have a plug shape. The first supports SP1 may prevent or reduce bending of the electrode stack 110G2 in a process of manufacturing the semiconductor device. The first supports SP1 may include an insulating material such as an oxide.

The second supports SP2 may be located in the peripheral circuit region PCR. The second supports SP2 may be located between the electrode stack 110G2 and the residual stack 110S. The second supports SP2 may extend in the second direction II. In other words, the second supports SP2 may have a line shape. The second supports SP2 may prevent the electrode stack 110G2 from being formed in an excessive region in the process of manufacturing the semiconductor device. In other words, the second supports SP2 may secure a region where the residual stack 110S remains. Therefore, contact plugs extending through the residual stack 110S and electrically connected to the peripheral circuit PC may be prevented from being damaged.

The first electrode structures 170 may be located in the peripheral circuit region PCR. The first electrode structures 170 may extend through the electrode stack 110G2. The first electrode structures 170 may be connected to the electrode layers 110C2 of the electrode stack 110G2. For example, the first electrode structures 170 may be electrically connected to the electrode layers 110C2. The first electrode structures 170 may be electrically connected to the peripheral circuit PC through the interconnection structure IC. The first electrode structures 170 may have a plug shape. The first electrode structures 170 may include a conductive material such as tungsten.

The second electrode structure 180 may be located in the peripheral circuit region PCR. The second electrode structure 180 may extend through the electrode stack 110G2. For example, the second electrode structure 180 may extend into the source structure SS through the electrode stack 110G2. Here, the insulating spacer 190 may surround a sidewall of the second electrode structure 180. In addition, the second contact vias 160 may be connected to at least one of the first electrode structures 170 or the second electrode structure 180.

The second electrode structure 180 may have a line shape extending in the first direction I. The second electrode structure 180 may be located at a level corresponding to the slit structure 140. The second electrode structure 180 may include a material different from a material of the first electrode structures 170. For example, the second electrode structure 180 may include polysilicon. The insulating spacer 190 may include an insulating material such as an oxide.

In accordance with embodiments of the present disclosure, in order to store a larger amount of data in a semiconductor device of a limited size, the cell region CR may be increased and the peripheral circuit region PCR may be decreased. In this instance, an area occupied by a capacitor in the peripheral circuit region PCR may be reduced. However, even though the peripheral circuit region PCR is limited, the first electrode structures 170, the electrode layers 110C2, the second electrode structure 180, and the insulating spacer 190 of the peripheral circuit region PCR may be used as a capacitor CS. For example, the first electrode structures 170 and the electrode layers 110C2 connected to the first electrode structures 170 may be used as a first electrode of the capacitor CS, the second electrode structure 180 may be used as a second electrode of the capacitor CS, and the insulating spacer 190 may be used as an insulating layer of the capacitor CS. Therefore, the capacitor CS separate from a capacitor included in the peripheral circuit PC may be configured in the peripheral circuit region PCR of a limited area.

A first bias may be applied to the first electrode structures 170. In this instance, the first bias may be applied to the electrode layers 110C2 connected to the first electrode structures 170. A second bias different from the first bias may be applied to the second electrode structure 180. Through this, the capacitor CS may be operated.

In addition, the capacitor CS may include a plurality of first electrode structures 170. In that instance, when applying the first bias, a resistance may be reduced by applying the first bias to the first electrode structures 170 separately. In other words, the resistance of the capacitor may be reduced by connecting the first electrode structures 170 in parallel.

According to the structure described above, the capacitor CS may be located on the peripheral circuit PC as well as the peripheral circuit PC. In other words, in addition to the capacitor included in the peripheral circuit PC, the first electrode structures 170, the electrode layers 110C2, the second electrode structure 180, and the insulating spacer 190 may be used as the capacitor CS.

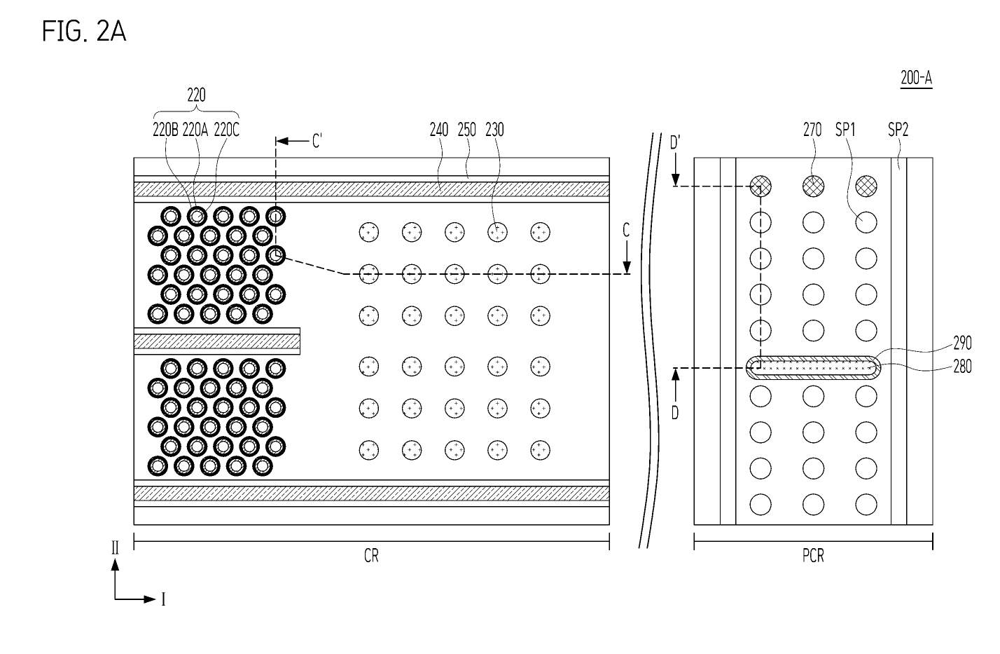

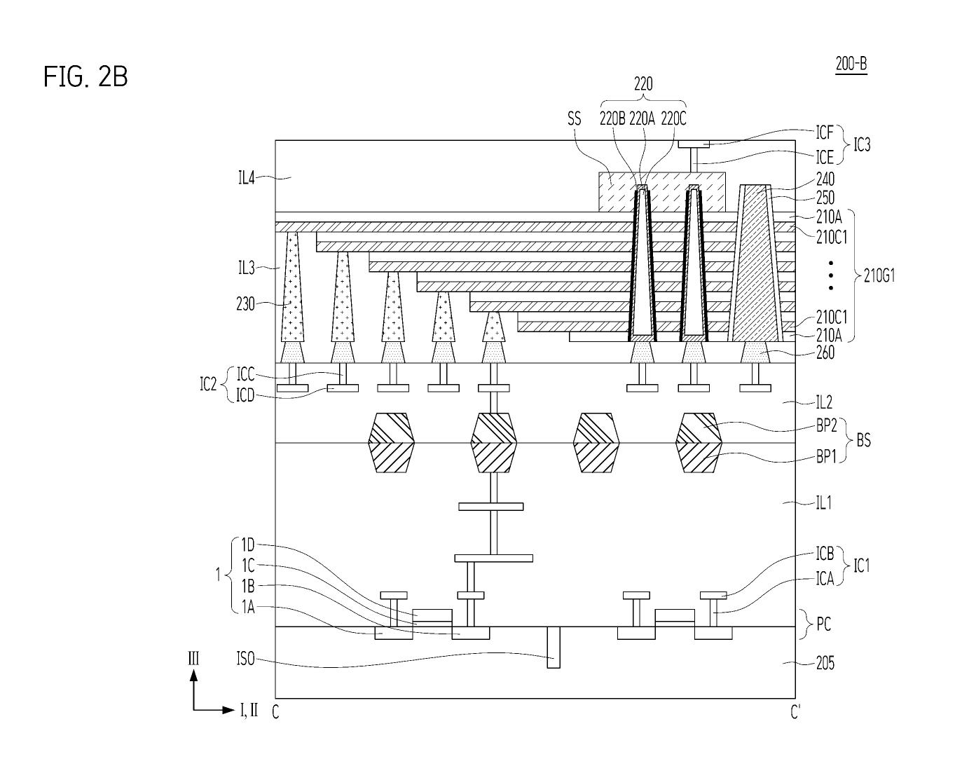

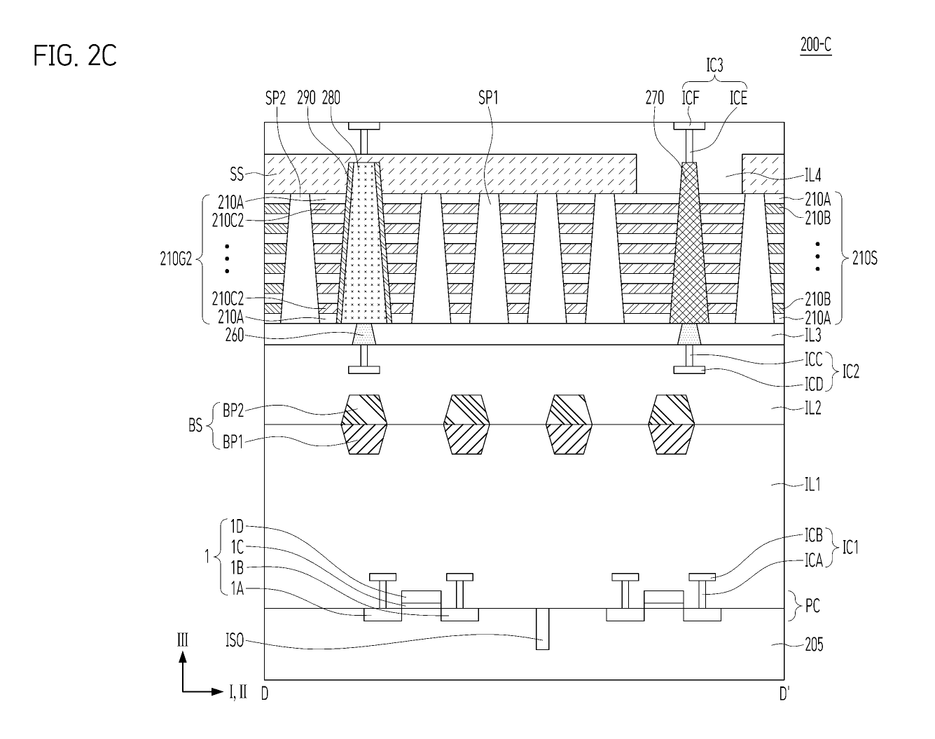

FIGS. 2A to 2C are views illustrating a semiconductor device 200 according to an embodiment of the present disclosure. FIG. 2A is a plan view (200-A), FIG. 2B is a C-C' cross-sectional view of FIG. 2A (200-B), and FIG. 2C is a D-D' cross-sectional view of FIG. 2A (200-C). Hereinafter, aspects that overlap the content described above are omitted.

Referring to FIGS. 2A to 2C, the semiconductor device 200 may include a substrate 205, a peripheral circuit PC, a source structure SS, a bonding structure BS, a gate structure 210G1, an electrode stack 210G2, a residual stack 210S, channel structures 220, first contact vias 230, a slit structure 240, a slit spacer 250, second contact vias 260, a first electrode structure 270, a second electrode structure 280, an insulating spacer 290, first supports SP1, second supports SP2, an element isolation layer ISO, a first interconnection structure IC1, a second interconnection structure IC2, a third interconnection structure IC3, a first interlayer insulating layer IL1, a second interlayer insulating layer IL2, a third interlayer insulating layer IL3, and a fourth interlayer insulating layer IL4.

The peripheral circuit PC may be located on the substrate 205. Here, the substrate 205 may include a cell region CR and a peripheral circuit region PCR. The peripheral circuit PC may include a transistor 1. The transistor 1 may include junctions 1A and 1B, a gate electrode 1D, and a gate insulating layer 1C. The element isolation layer ISO may be located in the substrate 205, an active region may be defined by the element isolation layer ISO, and the transistor 1 may be located in the active region.

The first interconnection structure IC1 may be located on the peripheral circuit PC. The first interconnection structure IC1 may be located in the first interlayer insulating layer IL1. Here, the first interlayer insulating layer IL1 may be located on the substrate 205. The first interconnection structure IC1 may include first vias ICA and first lines ICB. The first interconnection structure IC1 may include a conductive material such as tungsten. The first interlayer insulating layer IL1 may include an insulating material such as an oxide or a nitride.

The bonding structure BS may be located on the peripheral circuit PC. For example, the bonding structure BS may be located on the first interconnection structure IC1. The bonding structure BS may include first bonding pads BP1 and second bonding pads BP2. The first bonding pads BP1 may be located in the first interlayer insulating layer IL1. The second bonding pads BP2 may be located on the first bonding pads BP1, and may be located in the second interlayer insulating layer IL2. Here, the second interlayer insulating layer IL2 may be located on the first interlayer insulating layer IL1. The bonding structure BS may include a conductive material such as copper. The second interlayer insulating layer IL2 may include an insulating material such as an oxide or a nitride.

The second interconnection structure IC2 may be located on the bonding structure BS. The second interconnection structure IC2 may be located in the second interlayer insulating layer IL2. The second interconnection structure IC2 may include second vias ICC and second lines ICD. Although not shown in this figure, the second interconnection structure IC2 may be connected to the bonding structure BS. The second interconnection structure IC2 may include a conductive material such as tungsten.

The gate structure 210G1 may be located in the cell region CR. The gate structure 210G1 may include first insulating layers 210A and conductive layers 210C1 alternately stacked. The channel structures 220 may extend into the source structure SS through the gate structure 210G. Here, the source structure SS may be located on the gate structure 210G. Each of the channel structures 220 may include a channel layer 220A, a memory layer 220B surrounding the channel layer 220A, and an insulating core 220C in the channel layer 220A. The channel layer 220A may be connected to the source structure SS.

The first contact vias 230 may extend through the third interlayer insulating layer IL3, and may be connected to the conductive layers 210C1 of the gate structure 210G1, respectively. Here, the third interlayer insulating layer IL3 may be located on the second interlayer insulating layer IL2.

The slit structure 240 may extend through the gate structure 210G1. The slit structure 240 may extend into the fourth interlayer insulating layer IL4 through the gate structure 210G1. Here, the fourth interlayer insulating layer IL4 may be located on the gate structure 210G1. The slit spacer 250 may surround a sidewall of the slit structure 240. The slit structure 240 may include at least one of an insulating material, a semiconductor material, or a conductive material.

The electrode stack 210G2 may be located in the peripheral circuit region PCR. The electrode stack 210G2 may include first insulating layers 210A and electrode layers 210C2 alternately stacked. The first electrode structure 270 may extend through the electrode stack 210G2. For example, the first electrode structure 270 may pass through the electrode stack 210G2. The second electrode structure 280 may extend into the source structure SS through the electrode stack 210G2. Here, the insulating spacer 290 may surround a sidewall of the second electrode structure 280.

The residual stack 210S may be located in the peripheral circuit region PCR. However, the residual stack 210S is not limited thereto, and the residual stack 210S may extend from the peripheral circuit region PCR to the cell region CR. The residual stack 210S may include first insulating layers 210A and second insulating layers 210B alternately stacked.

The first supports SP1 may extend through the electrode stack 210G2. The first supports SP1 may have a plug shape. The second supports SP2 may be located between the residual stack 210S and the electrode stack 210G2. The second supports SP2 may have a line shape extending in a second direction II.

The second contact vias 260 may be connected to at least one of the channel structures 220, the first contact vias 230, the slit structure 240, the first electrode structure 270, and the second electrode structure 280. Here, the second contact vias 260 may be located on the second interconnection structure IC2, and may be located in the third interlayer insulating layer IL3. At least one of the second contact vias 260 may be electrically connected to the bonding structure BS through the second interconnection structure IC2.

The third interconnection structure IC3 may be located on the gate structure 210G1, the electrode stack 210G2, and the residual stack 210S. The third interconnection structure IC3 may be connected to the source structure SS or the first electrode structure 270. Here, the third interconnection structure IC3 may be located in the fourth interlayer insulating layer IL4. The fourth interlayer insulating layer IL4 may be located on the source structure SS, and may extend to a level corresponding to the source structure SS. For example, the fourth interlayer insulating layer IL4 may be located at a level corresponding to the source structure SS at a location corresponding to the first electrode structure 270.

According to the structure described above, the semiconductor device may include the bonding structure BS. The bonding structure BS may be located on the peripheral circuit PC, and the source structure SS may be located on the bonding structure BS. The bonding structure BS may be electrically connected to the peripheral circuit PC.

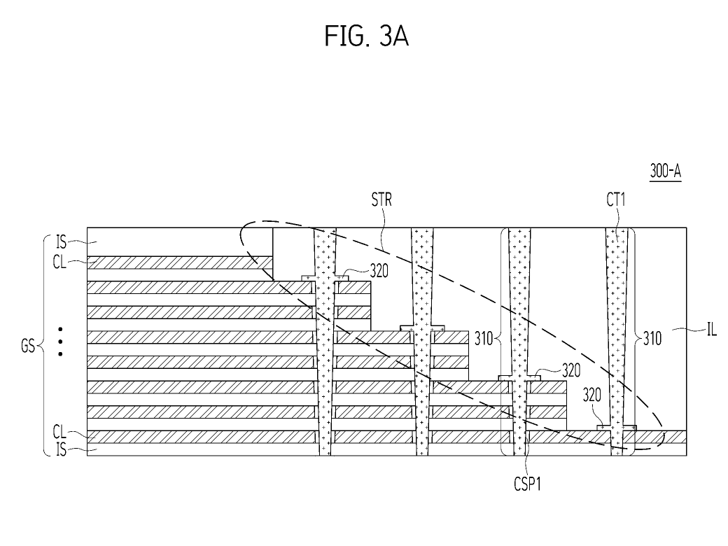

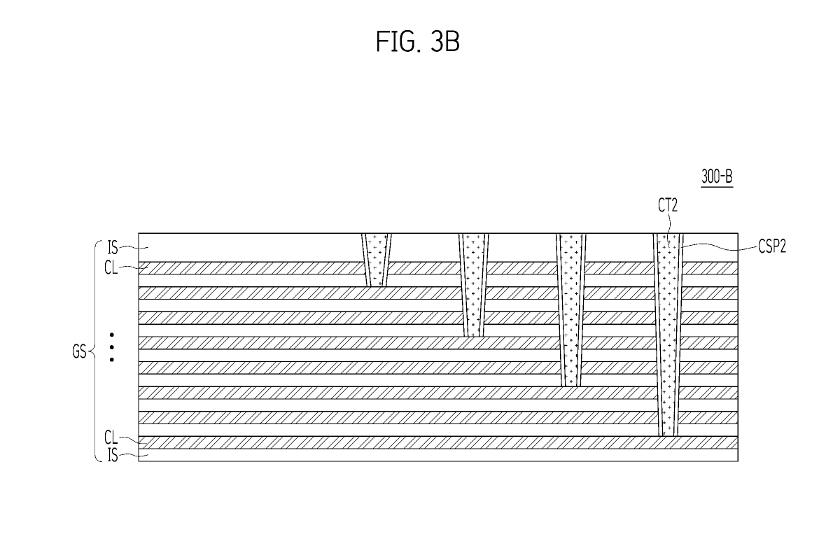

FIGS. 3A and 3B are illustrate cross-sectional views (300-A and 300-B) from different directions of a semiconductor device 300 according to an embodiment of the present disclosure. Hereinafter, aspects that overlap the content described above are omitted.

Referring to FIGS. 3A and 3B, the semiconductor device 300 may include a gate structure GS, an interlayer insulating layer IL, contact vias CT1 and CT2, and contact spacers CSP1 and CSP2.

Referring particularly to FIG. 3A, the gate structure GS may include insulating layers IS and conductive layers CL alternately stacked. The gate structure GS may include a step structure STR. An upper surface of at least one of the conductive layers CL of the gate structure GS may be in contact with the interlayer insulating layer IL. The interlayer insulating layer IL may include an insulating material such as an oxide.

The contact vias CT1 may extend through the interlayer insulating layer IL and the gate structure GS. Each of the contact vias CT1 may be connected to one of the conductive layers CL of the gate structure GS. For example, each of the contact vias CT1 may include a body portion 310 and a protrusion 320 protruding from the body portion 310, and may be connected to one of the conductive layers CL through the protrusion 320. Here, the protrusions 320 of the contact vias CT1 may be connected to the upper surface of the conductive layers CL. The contact vias CT1 may have substantially the same height. The contact vias CT1 may include a conductive material such as tungsten.

The contact spacers CSP1 may be located at a level corresponding to the conductive layers CL. The contact spacers CSP1 may prevent the conductive layers CL and the body portions 310 of the contact vias CT1 from being electrically connected. Here, the contact spacers CSP1 may include an insulating material such as an oxide.

Referring again to FIG. 3B, the gate structure GS may not include a step structure STR. The contact vias CT2 may extend through the gate structure GS. Each of the contact vias CT2 may be connected to one of the conductive layers CL of the gate structure GS. Each of the contact spacers CSP2 may surround a sidewall of the contact vias CT2. The contact spacers CSP2 may prevent remaining conductive layers CL except for the conductive layer CL connected to the contact via CT2 from being electrically connected to the contact via CT2. The contact vias CT2 may have different heights. The contact vias CT2 may include a conductive material such as tungsten, and the contact spacers CSP2 may include an insulating material such as an oxide.

For reference, the gate structure GS may correspond to the gate structure 110G1 of FIG. 1B and the gate structure 210G1 of FIG. 2B. In addition, the contact vias CT1 and CT2 may correspond to the first contact vias 130 of FIG. 1B and the first contact vias 230 of FIG. 2B.

In other words, the gate structures 110G1 and 210G1 of FIGS. 1B and 2B may include a step structure STR. In this case, the contact vias 130 and 230 may extend through the interlayer insulating layers IL2 and IL3 and the gate structure 110G1 and 210G1. In addition, each of the contact vias 130 and 230 may include a body portion and a protrusion 320 protruding from the body portion 310, and may be connected to one of the conductive layers 110C1 and 210C1 of the gate structure 110G1 and 210G1 through the protrusion 320. Here, the contact spacers CSP1 may be located at a level corresponding to the conductive layers 110C1 and 210C1.

In addition, the gate structures 110G1 and 210G1 of FIGS. 1B and 2B may not include the step structure STR. In this instance, the contact vias 130 and 230 may extend through the gate structure 110G1 and 210G1, and may be connected to one of the conductive layers 110C1 and 210C1 of the gate structure 110G1 and 210G1. Here, the contact spacers CSP2 may surround a sidewall of the contact vias 130 and 230.

According to the structure described above, the gate structure GS may include the step structure GS. Here, the contact vias CT1 and CT2 may extend through the gate structure GS. Each of the contact vias CT1 may be connected to the conductive layer CL through the protrusion 320, and the contact spacers CPS1 may be located at a level corresponding to the conductive layers CL.

In addition, the gate structure GS may not include the step structure GS. Here, each of the contact vias CT2 may extend through the gate structure GS, and may be connected to the conductive layer CL. The contact spacers CSP2 may surround the sidewall of the contact vias CT2.

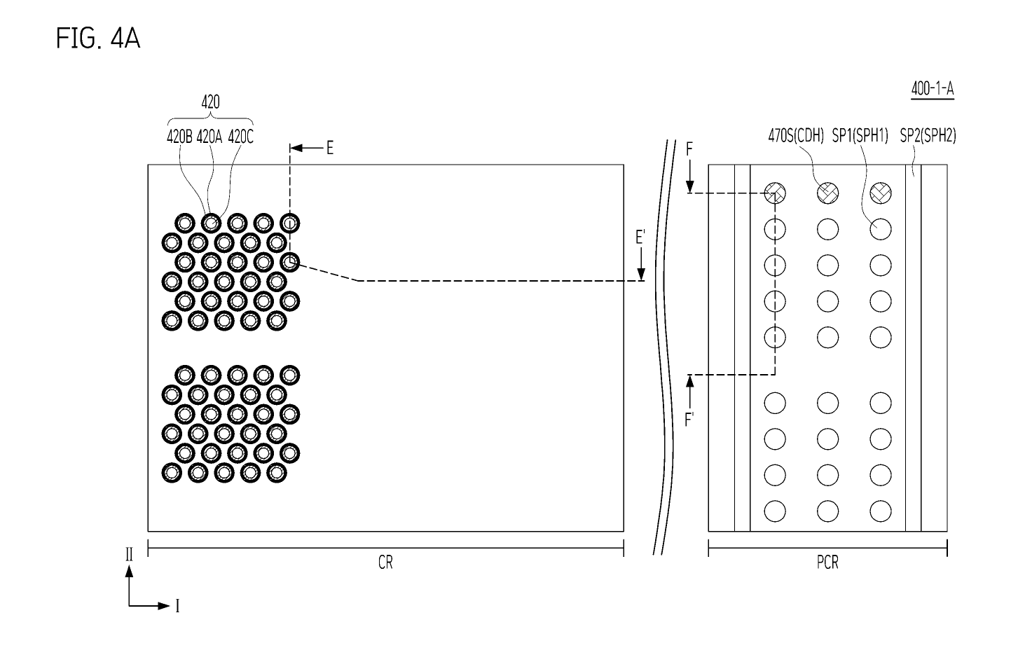

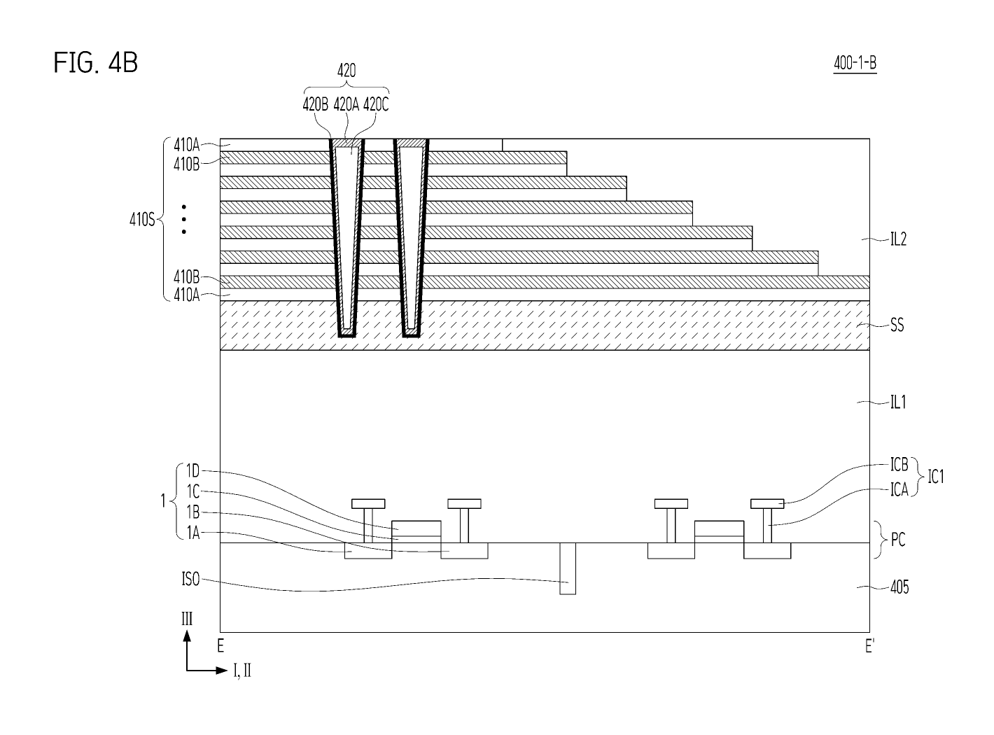

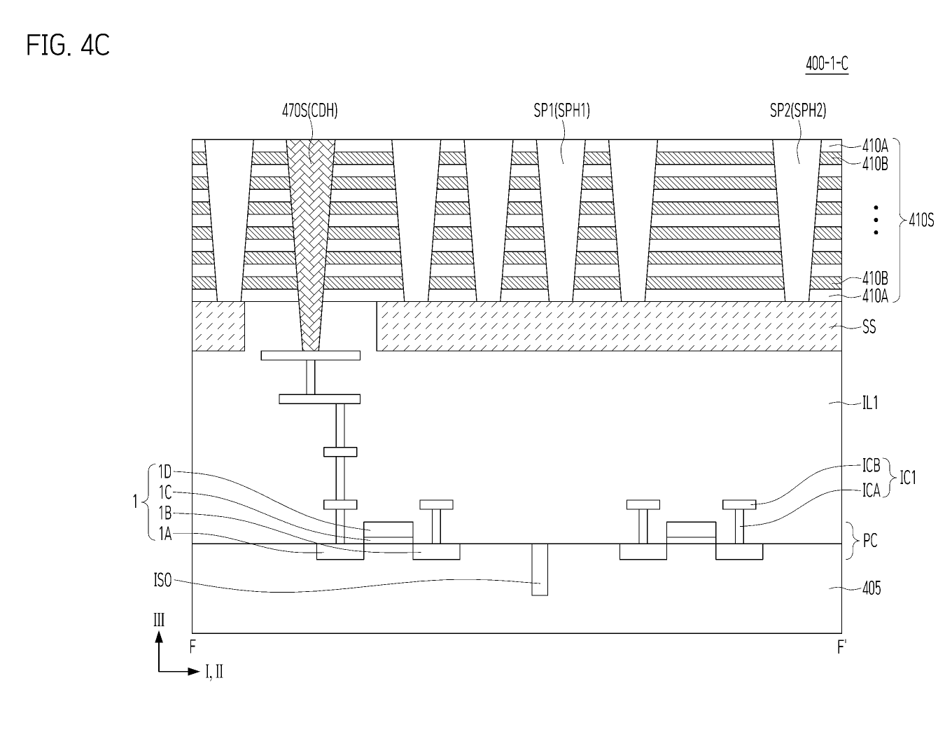

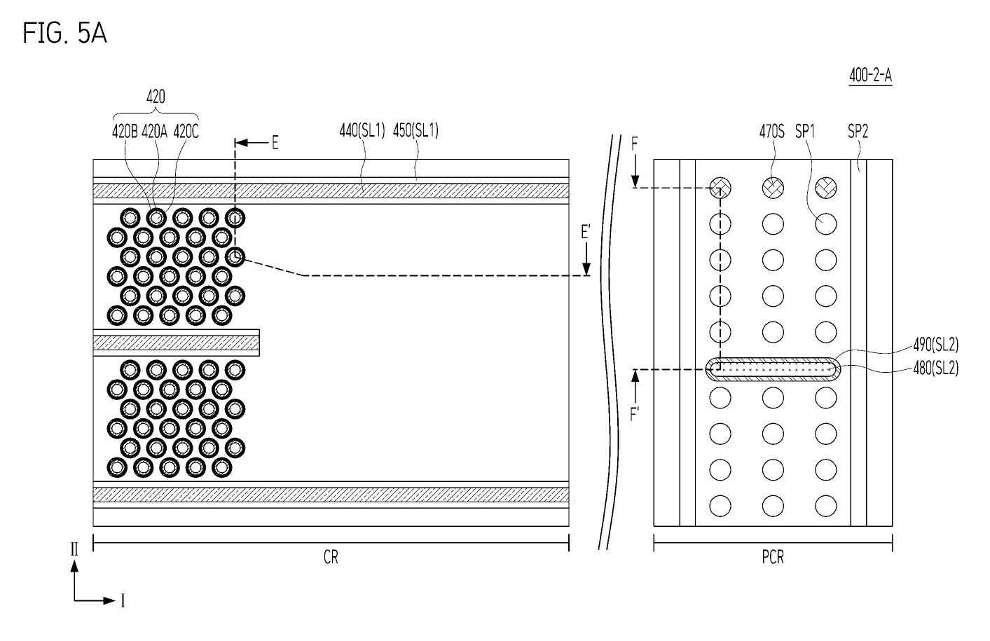

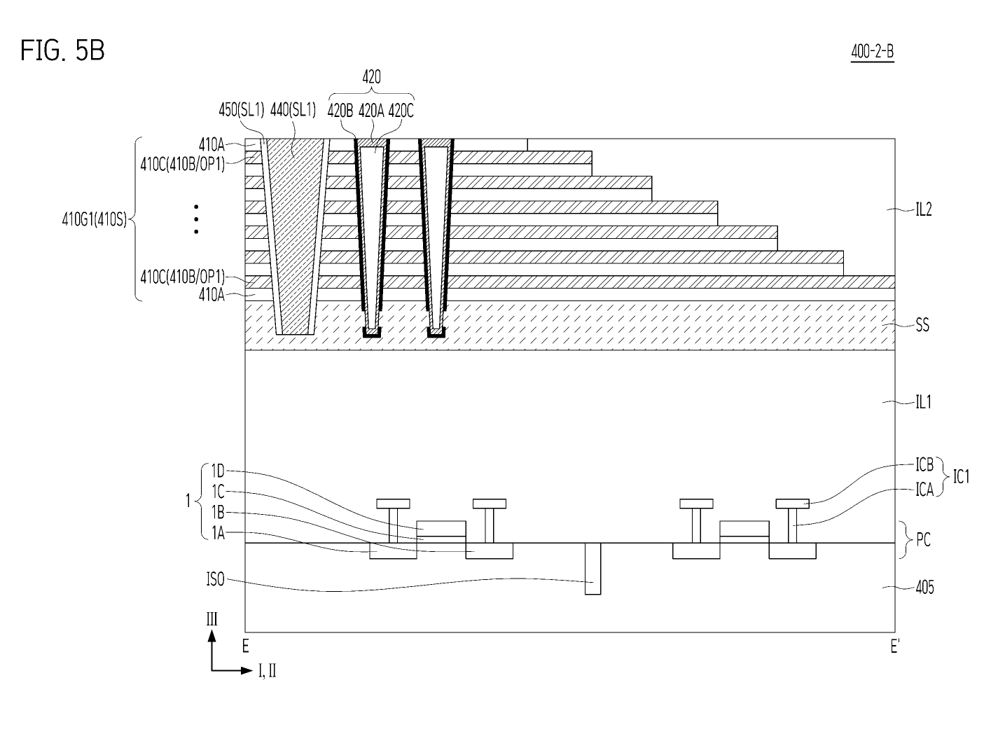

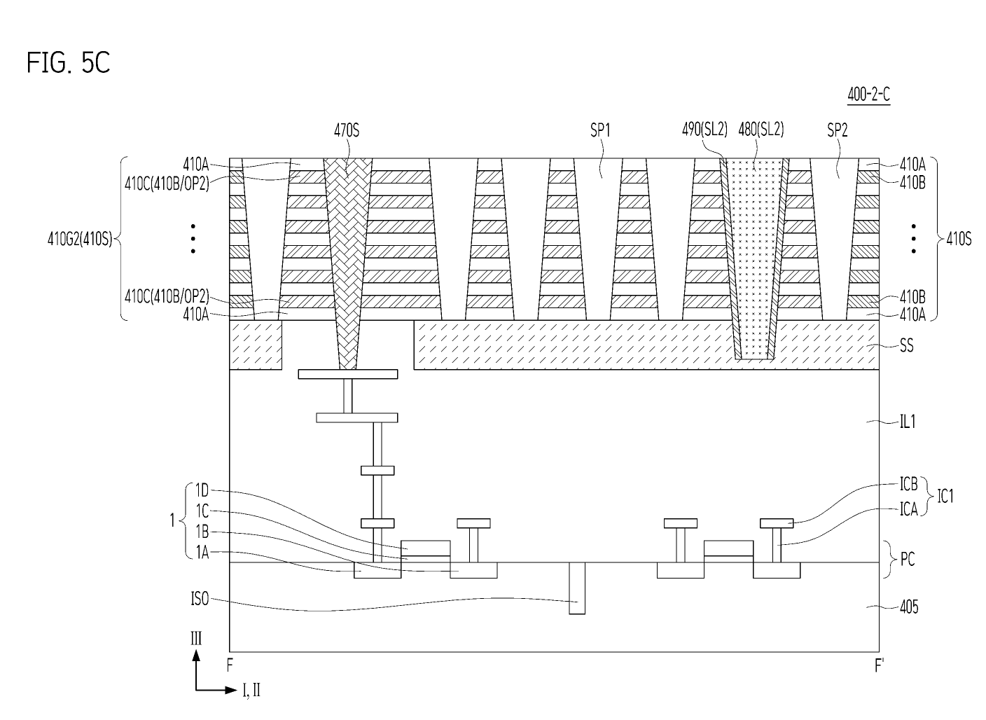

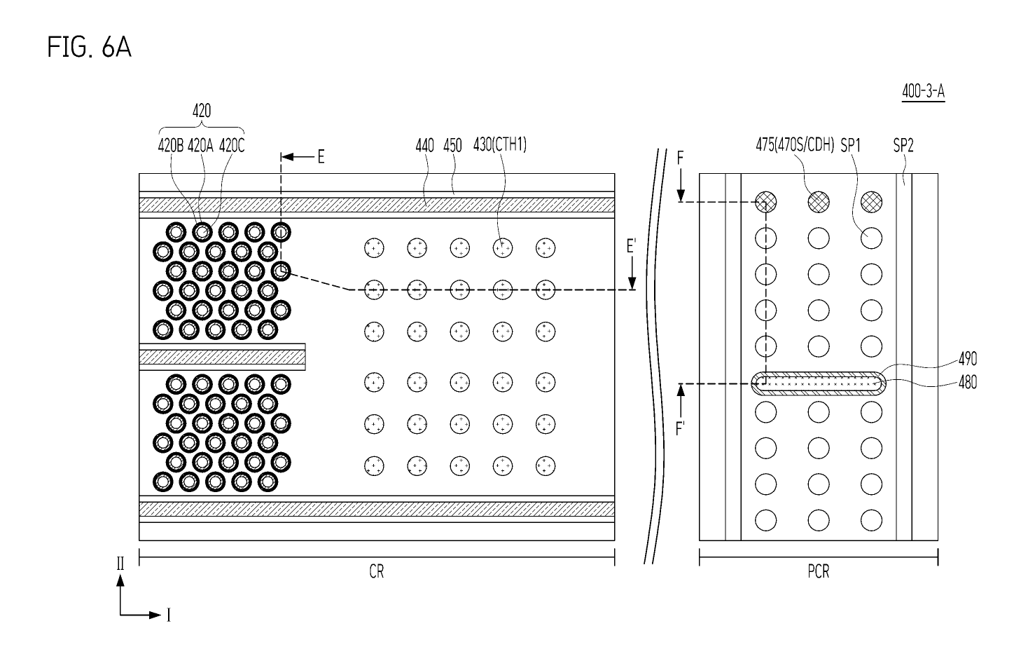

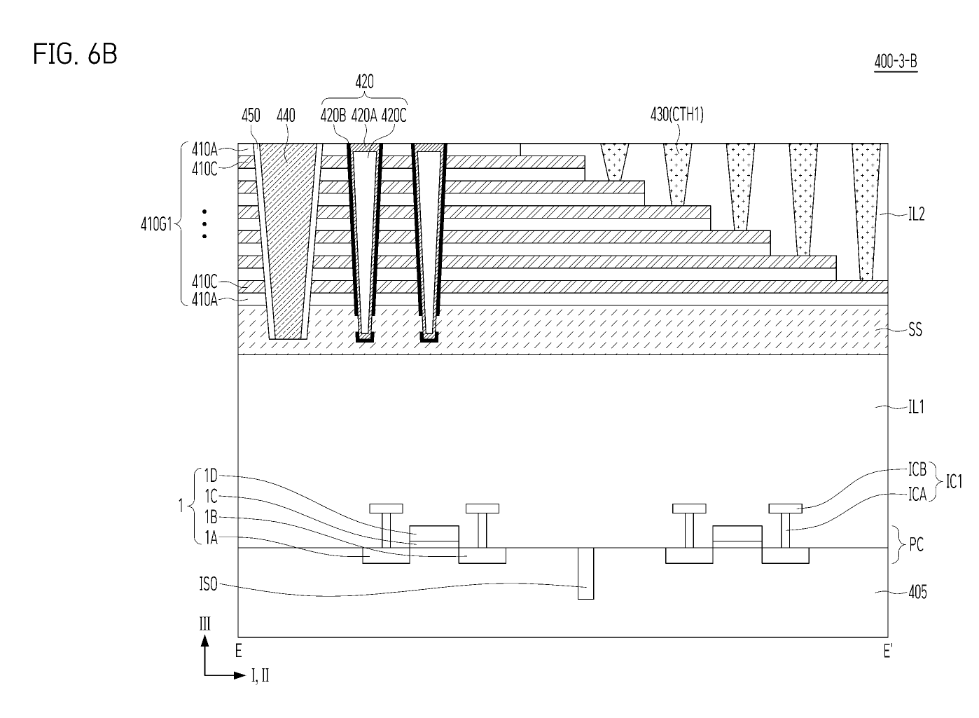

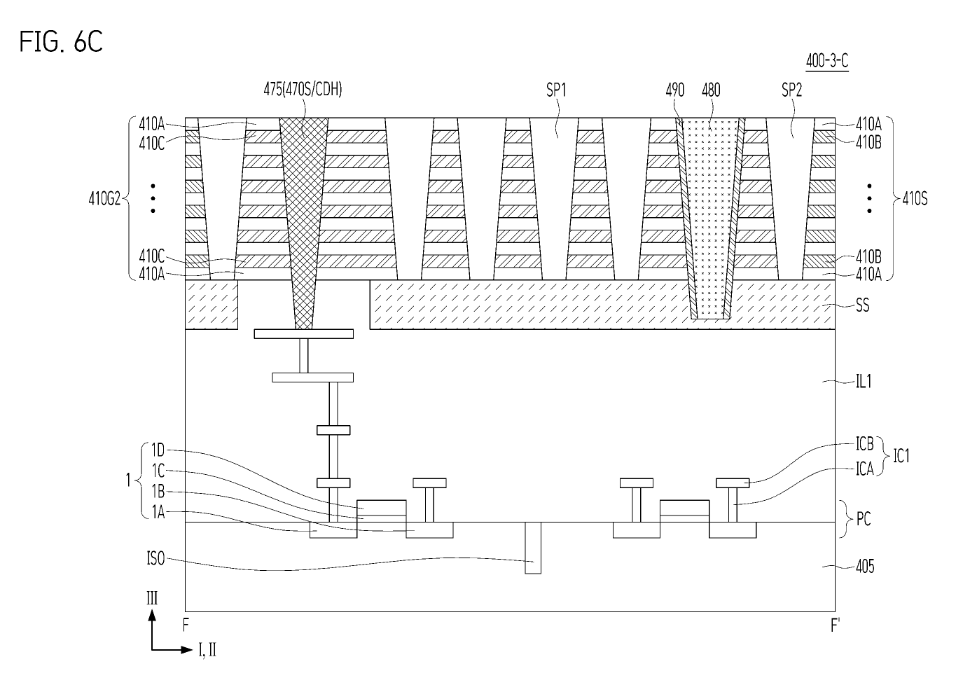

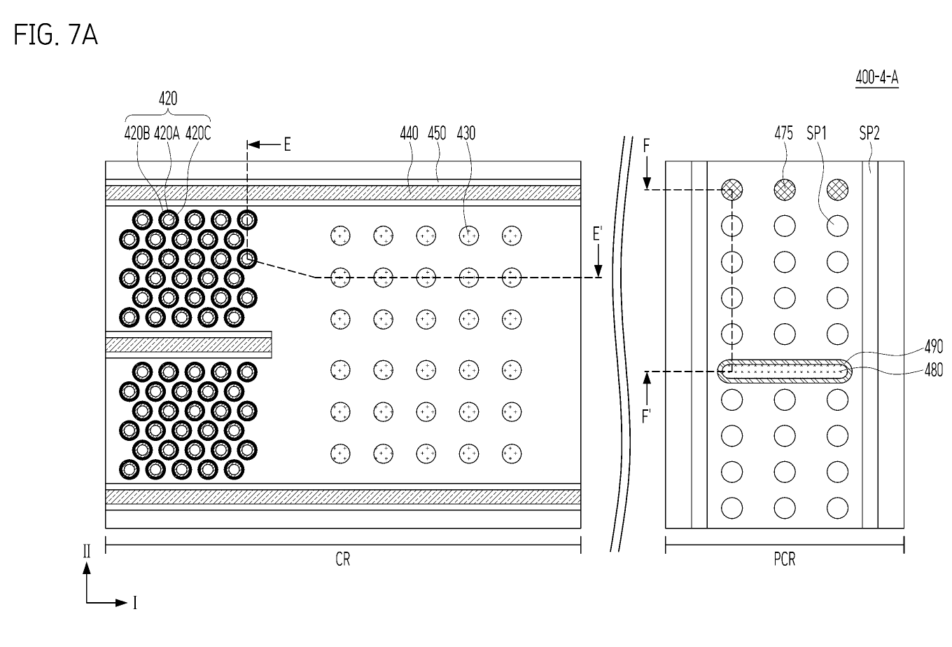

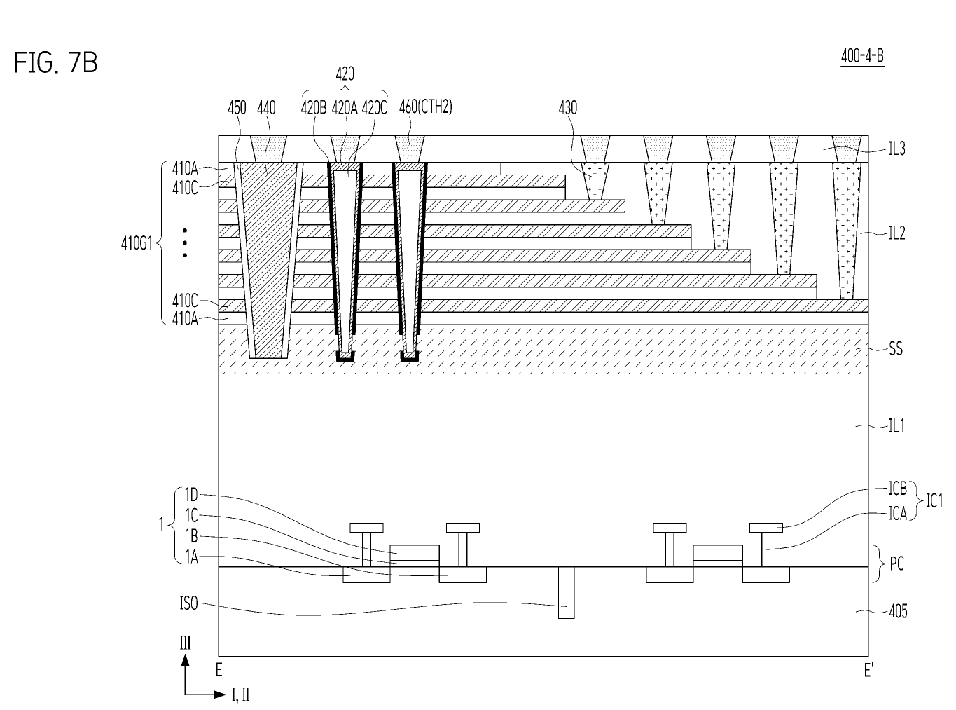

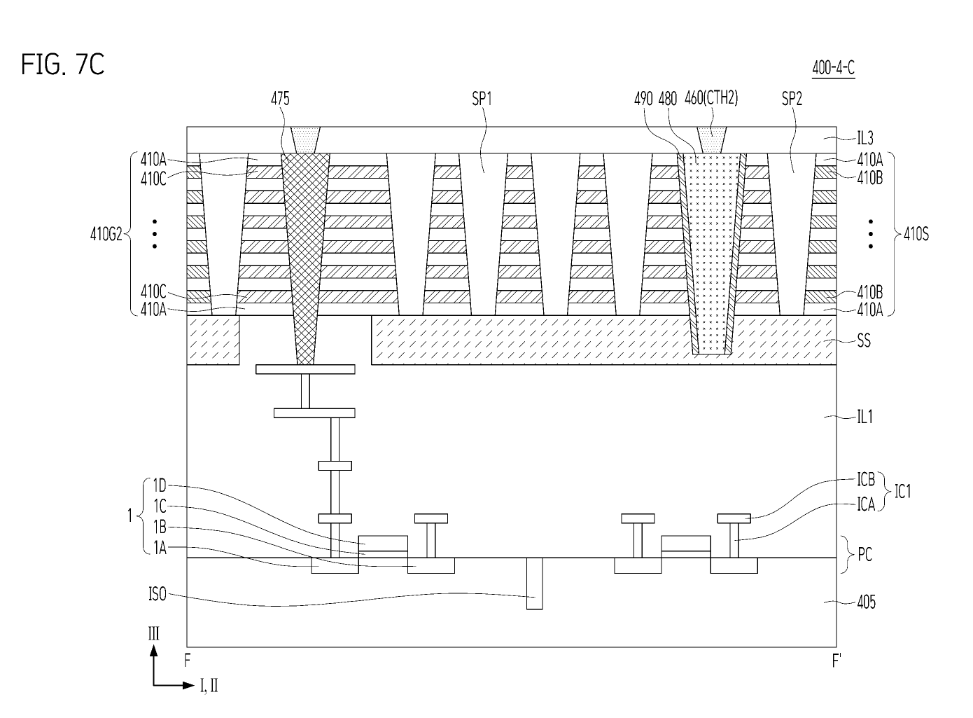

FIGS. 4A (400-1-A), FIG. 4B (400-1-B), FIG. 4C (400-1-C), FIG. 5A (400-2-A), FIG. 5B (400-2-B), FIG. 5C (400-2-C), FIG. 6A (400-3-A), FIG. 6B (400-3-B), FIG. 6C (400-3- C), FIG. 7A (400-4-A), FIG. 7B (400-4-B), and FIG. 7C (400-4-C) are views illustrating a method of manufacturing a semiconductor device 400 according to an embodiment of the present disclosure. FIGS. 4A, 5A, 6A, and 7A are plan views, FIGS. 4B, 5B, 6B, and 7B are E-E' cross-sectional views of respective FIGS. 4A, 5A, 6A, and 7A, and FIGS. 4C, 5C, 6C, and 7C are F-F' cross-sectional views of respective FIGS. 4A, 5A, 6A, and 7A. Hereinafter, aspects that overlap the content described above are omitted.

Referring to FIGS. 4A to 4C (steps 400-3-A to 400-3-C of the method of manufacturing a semiconductor device 400), a peripheral circuit PC may be formed on a substrate 405 including a cell region CR and a peripheral circuit region PCR. The peripheral circuit PC may include a transistor 1, a capacitor, and the like. The transistor 1 may include junctions 1A and 1B, a gate electrode 1D, and a gate insulating layer 1C. Here, the gate insulating layer 1C may be located between the gate electrode 1D and the substrate 405. An element isolation layer ISO may be located in the substrate 405, an active region may be defined by the element isolation layer ISO, and the transistor 1 may be located in the active region.

Subsequently, an interconnection structure IC may be formed on the peripheral circuit PC. The interconnection structure IC may be formed in a first interlayer insulating layer IL1. Here, the first interlayer insulating layer IL1 may be formed on the substrate 405. The interconnection structure IC may include vias ICA and lines ICB.

The interconnection structure IC may be connected to the peripheral circuit PC. For example, at least one of the vias ICA may be connected to the transistor 1. At least one of the vias ICA may interconnect the lines ICB. The lines ICB may interconnect the vias ICA. The interconnection structure IC1 may include a conductive material such as tungsten. The first interlayer insulating layer IL1 may include an insulating material such as an oxide.

Subsequently, a stack 410S may be formed on the substrate 405. For example, the stack 410S may be formed by alternately stacking first material layers 310A and second material layers 310B. Here, the stack 410S formed in the cell region CR may have a step structure in which an upper surface of the second material layers 410B is exposed. In this case, a second interlayer insulating layer IL2 may be formed on the step structure. However, the stack 410S is not limited thereto, and the stack 410S may not include the step structure. The first material layers 410A may include an insulating material such as an oxide, and the second material layers 410B may include a sacrificial material such as a nitride.

Before forming the stack 410S, a source structure SS may be formed on the substrate 405. Here, the source structure SS may extend from the cell region CR to the peripheral circuit region PCR. The source structure SS may be partially removed from the peripheral circuit region PCR. For example, a portion of the source structure SS may be removed in consideration of a region where a first electrode structure is to be formed. In this instance, an interlayer insulating layer IL1 may be formed in a region where the source structure SS is removed. The source structure SS may include polysilicon and/or materials that fulfill a similar function in the semiconductor device 400.

In the cell region CR, channel structures 320 extending through the stack 410S may be formed. For example, the channel structures 420 extending into the source structure SS through the stack 410S may be formed. Here, the channel structures 420 may be arranged in a first direction I and a second direction II intersecting with the first direction I. Each of the channel structures 420 may include a channel layer 420A, a memory layer 420B surrounding the channel layer 420A, and an insulating core 420C in the channel layer 420A.

In the peripheral circuit region PCR, first supports SP1 and second supports SP2 extending through the stack 410S may be formed. First, first support holes SPH1 and second support holes SPH2 extending through the stack 410S may be formed. Here, the first support holes SPH1 may have a plug shape, and the second support holes SPH2 may have a line shape extending in the second direction II. Subsequently, an insulating material such as an oxide may be formed in the first support holes SPH1 and the second support holes SPH2. Accordingly, the first supports SP1 may be formed in the first support holes SPH1, and the second supports SP2 may be formed in the second support holes SPH2.

In the peripheral circuit region PCR, electrode sacrificial layers 470S extending through the stack 410S may be formed. First, electrode holes CDH extending through (for example, penetrating through) the stack 410S may be formed. The first and second support holes SPH1 and SPH2 may be formed by forming the electrode holes CDH. Subsequently, an insulating material such as an oxide may be formed in the electrode holes CDH. The electrode sacrificial layers 470S may be formed in the electrode holes CDH. The electrode sacrificial layers 470S may be formed when forming the first and second supports SP1 and SP2.

Referring to FIGS. 5A to 5C (steps 400-2-A to 400-2-C of the method of manufacturing a semiconductor device 400), first slits SL1 extending through the stack 410S in the cell region CR may be formed. Second slits SL2 extending through the stack 410S in the peripheral circuit region PCR may be formed. When forming the first slit SL1, the second slit SL2 may be formed. Here, the first slit SL1 and the second slit SL2 may have a line shape extending in the first direction I.

Subsequently, first openings OP1 may be formed by removing the second material layers 410B of the stack 410S through the first slits SL1. Subsequently, third material layers 410C may be formed in the first openings OP1. Here, the third material layers 410C of the cell region CR may be used as conductive layers. Accordingly, a gate structure 410G1 in which the first material layers 410A and the third material layers 410C are alternately stacked may be formed. Subsequently, a source opening may be formed by removing a portion of the source structure SS through the first slits SL1. After exposing the channel layer 420A by partially etching the memory layer 420B of the channel structures 420 through the source opening, the source structure SS and the channel layer 420A may be connected by forming a semiconductor material in the source opening.

Second openings OP2 may be formed by removing the second material layers 410B of the stack 410S through the second slit SL2. When forming the first openings OP1, the second openings OP2 may be formed. Subsequently, the third material layers 410C may be formed in the second openings OP2. Here, the third material layers 410C of the peripheral circuit region PCR may be used as electrode layers. In other words, the third material layers 410C may be used as an electrode of a capacitor CS. Accordingly, an electrode stack 410G2 in which the first material layers 410A and the third material layers 410C are alternately stacked may be formed.

When the second material layers 410B include a conductive material, a process of replacing the second material layers 410B with the third material layers 410C may be omitted. In this case, the stack 410S of the cell region CR may be used as the gate structure 410G1, and the stack 410S of the peripheral circuit region PCR may be used as the electrode stack 410G2.

A portion of the stack 410S, which is not formed as the electrode stack 410G2, may be defined as a residual stack. The second supports SP2 of the line shape may prevent the electrode stack 410G2 from expanding to an excessive region. In other words, the second supports SP2 may secure a region where the residual stack is to be remained. In this case, even though contact plugs extending through the residual stack to be electrically connected to the peripheral circuit PC are formed, the contact plugs may be prevented from being electrically connected to the electrode stack 410G2.

Subsequently, a slit insulating layer may be formed in the first slit SL1. Subsequently, the source structure SS may be exposed by etching a lower surface of the slit insulating layer. In this process, the slit insulating layer may be separated to form a slit spacer 450. Here, the slit spacer 450 may include an insulating material such as an oxide. Subsequently, a slit structure 460 may be formed in the first slit SL1. Here, the slit structure 460 may include polysilicon and/or materials that fulfill a similar function.

An insulating layer may be formed in the second slit SL2. Subsequently, the source structure SS may be exposed by etching a lower surface of the insulating layer. In this process, the insulating layer may be separated to form an insulating spacer 490. When forming the slit insulating layer, the insulating layer may be formed. In addition, when forming the slit spacer 450, the insulating spacer 490 may be formed. Subsequently, a second electrode structure 480 may be formed in the second slit SL2. When forming the slit structure 460, a second electrode structure 480 may be formed. Here, the second electrode structure 480 may be used as an electrode of the capacitor CS.

Referring to FIGS. 6A to 6C (steps 400-3-A to 400-3-C of the method of manufacturing a semiconductor device 400), first contact holes CTH1 respectively exposing the third material layers 410C of the gate structure 410G1 in the cell region CR may be formed. In other words, before forming the third material layers 410C, the first contact holes CTH1 respectively exposing a location where the second material layers 410B are formed may be formed. For example, the first contact holes CTH1 may be formed by etching the second interlayer insulating layer IL2. Subsequently, first contact vias 430 may be formed in the first contact holes CTH1, respectively. For example, the first contact vias 430 may be formed by forming a conductive material such as tungsten in the first contact holes CTH1.

The electrode holes CDH electrode may be opened by removing the sacrificial layers 470S in the peripheral circuit region PCR. When forming the first contact holes CTH1, the electrode holes CDH may be formed. For example, when etching the interlayer insulating layer IL2, the electrode sacrificial layers 470S may be removed. Subsequently, the first electrode structures 475 may be formed in the electrode holes CDH. When forming the first contact vias 330, the first electrode structures 475 may be formed. The first electrode structures 475 may include a conductive material such as tungsten. Here, the first electrode structure 475 may be used as an electrode of the capacitor CS.

According to an embodiment of the present disclosure, the first electrode structures 475, the electrode layers, the second electrode structure 480, and the insulating spacer 490 of the peripheral circuit region PCR may be used as the capacitor CS. For example, the first electrode structures 475 and the electrode layers 310C2 connected to the first electrode structures 475 may be used as a first electrode of the capacitor CS, the second electrode structure 480 may be used as a second electrode of the capacitor CS, and the insulating spacer 490 may be used as an insulating layer of the capacitor CS. Therefore, the capacitor CS separate from a capacitor included in the peripheral circuit PC may be configured in the peripheral circuit region PCR of a limited area.

Referring to FIGS. 7A to 7C (steps 400-4-A to 400-4-C of the method of manufacturing a semiconductor device 400), second contact vias 460 may be formed in a third interlayer insulating layer IL3. For example, the second contact vias 460 may be formed in the cell region CR and the peripheral circuit region PCR. Here, the third interlayer insulating layer IL3 may be formed on the gate structure 410G1, the electrode stack 410G2, and the residual stack. First, second contact holes CTH2 exposing at least one of the channel structures 420, the first contact vias 430, the slit structure 440, the first electrode structure 475, and the second electrode structure 480 may be formed. Subsequently, the second contact vias 460 may be formed in the second contact holes CTH2. Here, the second contact vias 460 may include a conductive material such as tungsten.

According to the manufacturing method described above, the capacitor CS formed in the peripheral circuit region PCR may be formed by utilizing a process of forming structures formed in the cell region CR. In other words, when forming structures of the cell region CR, structures for forming the capacitor CS may be formed simultaneously. Therefore, by unifying a process of the cell region CR and the peripheral circuit region PCR, a manufacturing cost of the semiconductor device may be reduced.

For example, when forming the first and second support holes SPH1 and SPH2, the electrode holes CDH may be formed. When forming the first and second supports SP1 and SP2, the electrode sacrificial layers 470S may be formed. When forming the first slit SL1, the second slit SL2 may be formed. When forming the conductive layers, the electrode layers may be formed. When forming the slit structure 460, the second electrode structure 480 may be formed.

In addition, in addition to the capacitor included in the peripheral circuit PC, the first electrode structures 475, the electrode layers, the second electrode structure 480, and the insulating spacer 490 may be used as the capacitor CS.

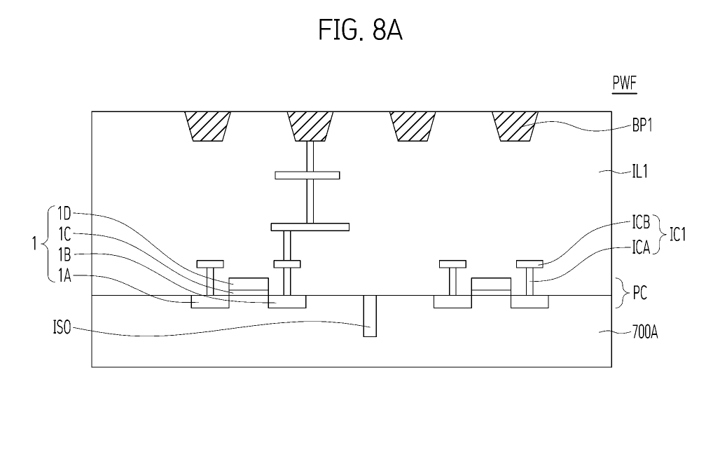

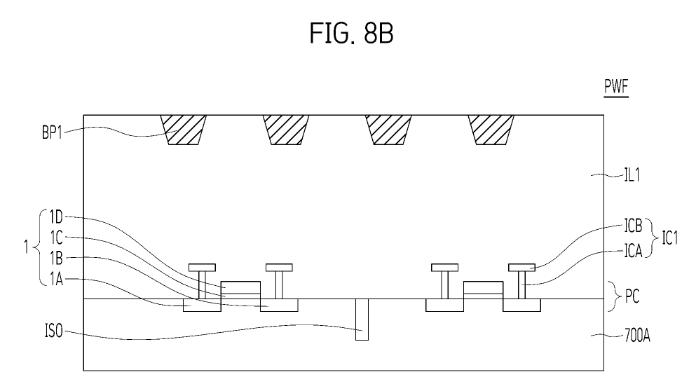

FIGS. 8A, 8B, 9A, 9B, 10A, and 10B are views illustrating a method of manufacturing a semiconductor device according to an embodiment of the present disclosure. Hereinafter, a content that overlaps the content described above is omitted.

Referring to FIGS. 8A and 8B, a peripheral circuit wafer PWF may be formed. For example, the peripheral circuit wafer PWF including a peripheral circuit PC and first bonding pads BP1 may be formed.

First, the peripheral circuit PC may be formed on a peripheral circuit substrate 700A. Here, the peripheral circuit substrate 700A may include a cell region CR and a peripheral circuit region PCR. FIG. 8A shows the cell region CR of the peripheral circuit substrate 700A, and FIG. 8B shows the peripheral circuit region PCR of the peripheral circuit substrate 700A.

Subsequently, a first interconnection structure IC1 may be formed on the peripheral circuit PC. The first interconnection structure IC1 may be formed in a first interlayer insulating layer IL1. Here, the first interlayer insulating layer IL1 may be formed on the peripheral circuit substrate 700A. The first interconnection structure IC1 may include first vias ICA and first lines ICB. The first interconnection structure IC1 may be connected to the peripheral circuit PC. For example, at least one of the first vias ICA may be connected to the peripheral circuit PC.

Subsequently, the first bonding pads BP1 may be formed on the first interconnection structure IC1. The first bonding pads BP1 may be formed in the first interlayer insulating layer IL1. The first bonding pads BP1 may be connected to the first interconnection structure IC1. For example, at least one of the first bonding pads BP1 may be connected to the first via ICA. The first bonding pads BP1 may include a conductive material such as copper.

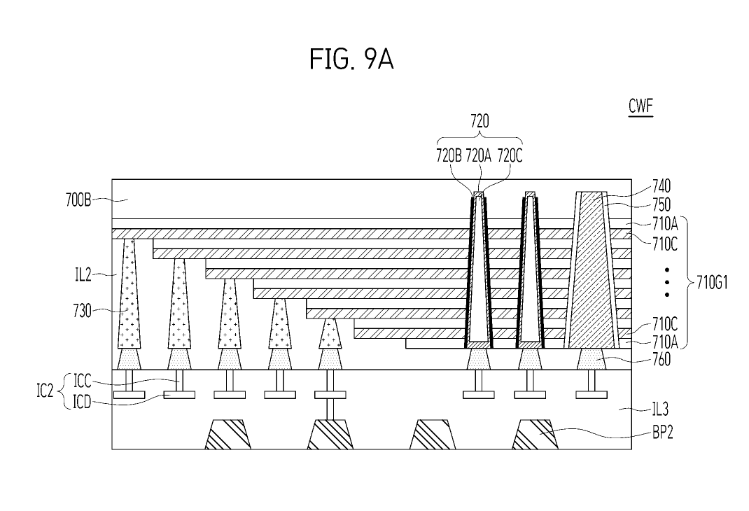

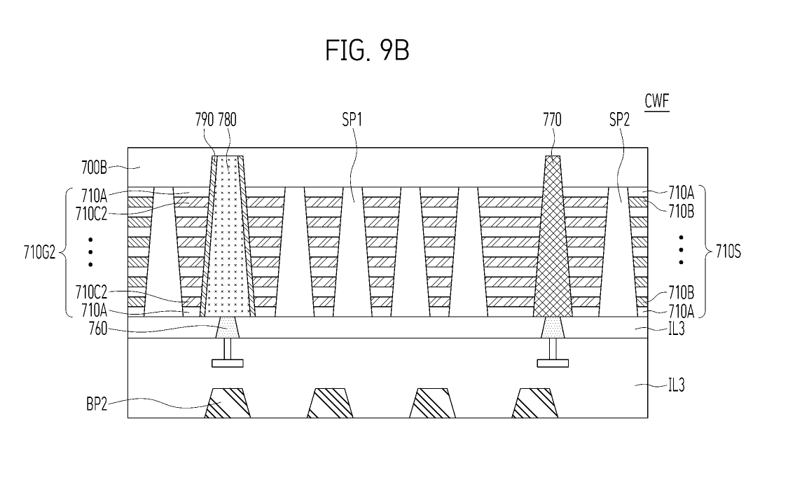

Referring to FIGS. 9A and 9B, a cell wafer CWF may be formed. For example, the cell wafer CWF including second bonding pads BP2, first electrode structures 770, electrode layers, a second electrode structure 780, and an insulating spacer 790 may be formed.

For reference, FIGS. 9A and 9B may show a state in which the cell wafer CWF is rotated. Therefore, terms such as over and under used to describe a location relationship between structures in the description of the disclosure are for convenience of description, and may be for description in a state in which the cell wafer CWF is not rotated.

A cell substrate 700B may include a cell region and a peripheral circuit region. FIG. 8A shows the cell region of the cell substrate 700B, and FIG. 8B shows the peripheral circuit region of the cell substrate 700B.

A stack 710S, a gate structure 710G1, an electrode stack 710G2, channel structures 720, first contact vias 730, a slit structure 740, a slit spacer 750, second contact vias 760, a first electrode structure 770, a second electrode structure 780, an insulating spacer 790, first supports SP1, and second supports SP2 may be formed on the cell substrate 700B.

The channel structures 720 may extend into the cell substrate 700B through the gate structure 710G1. The slit structure 740 and the slit spacer 750 may extend into the cell substrate 700B through the gate structure 710G1. The first electrode structure 770 may extend into the cell substrate 710G2 through the electrode stack 710G2. The second electrode structure 780 and the insulating spacer 790 may extend into the cell substrate 710G2 through the electrode stack 710G2. Here, the first electrode structure 770, the electrode layers, the second electrode structure 780, and the insulating spacer 790 of the cell wafer CWF may be used as a capacitor CS.

In addition, a method of forming the stack 710S, the gate structure 710G1, the electrode stack 710G2, the channel structures 720, the first contact vias 730, the slit structure 740, the slit spacer 750, the second contact vias 760, the first electrode structure 770, the second electrode structure 780, the insulating spacer 790, the first supports SP1, and the second supports SP2 on the cell substrate 700B may be equal/similar to the method of forming the stack 410S, the gate structure 410G1, the electrode stack 410G2, the channel structures 420, the first contact vias 430, the slit structure 440, the slit spacer 450, the second contact vias 460, the first electrode structure 475, the second electrode structure 480, the insulating spacer 490, the first supports SP1, and the second supports SP2 through FIGS. 4A to 7C.

Subsequently, a second interconnection structure IC2 may be formed on the second contact vias 760. The second interconnection structure IC2 may include second vias ICC and second lines ICD. The second interconnection structure IC2 may be formed in a third interlayer insulating layer IL3. The third interlayer insulating layer IL3 may be formed on the second interlayer insulating layer IL2. The second interconnection structure IC2 may be connected to the second contact vias 760. For example, at least one of the second vias ICC may be connected to the second contact vias 760.

Subsequently, second bonding pads BP2 may be formed on the second interconnection structure IC2. The second bonding pads BP2 may be connected to the second interconnection structure IC2. For example, at least one of the second bonding pads BP2 may be connected to the second via ICC. The second bonding pads BP2 may include a conductive material such as copper.

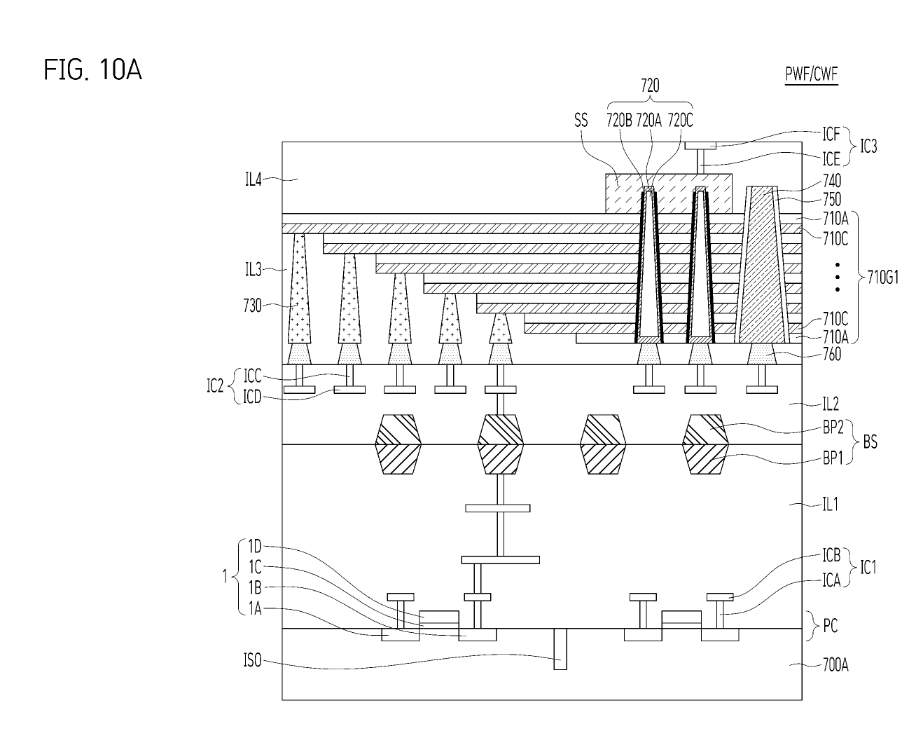

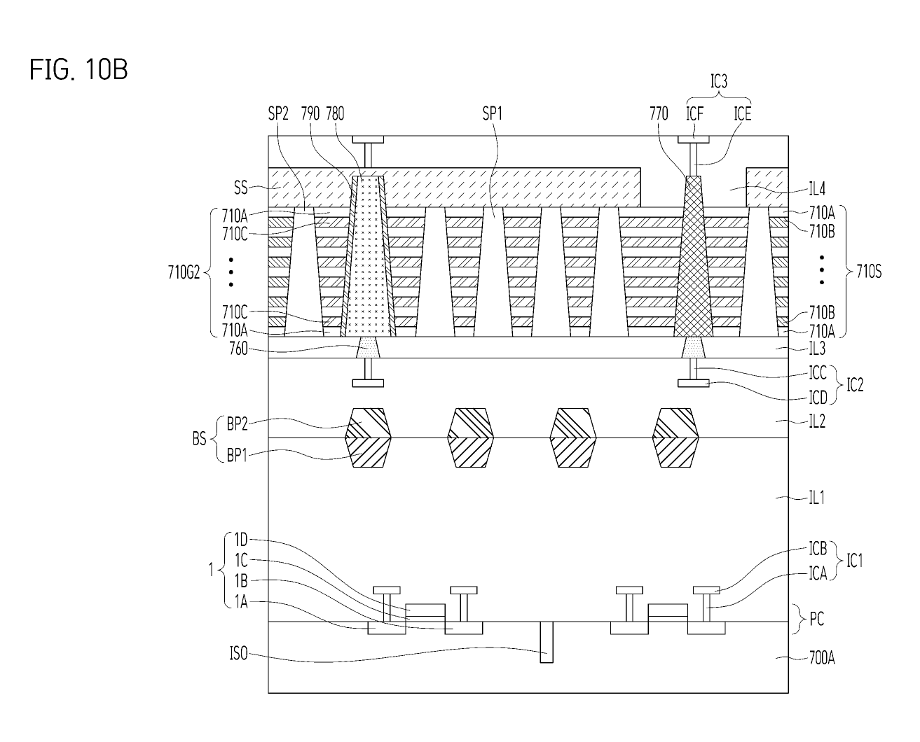

Referring to FIGS. 10A and 10B, the peripheral circuit wafer PWF and the cell wafer CWF may be bonded. For example, the first bonding pads BP1 and the second bonding pads BP2 may be bonded. Therefore, the peripheral circuit wafer PWF and the cell wafer CWF may be electrically connected.

Subsequently, the cell substrate 700B may be removed. In this case, the channel structures 720, the slit structure 740, the slit spacer 750, the first electrode structure 770, the second electrode structure 780, and the insulating spacer 790 may be exposed.

Subsequently, a channel layer 720A may be exposed by partially removing a memory layer 720B of the channel structures 720. Subsequently, a source structure SS may be formed on the channel structures 720. Here, the channel layer 720A may be connected to the source structure SS. In addition, the source structure SS may be formed on the second electrode structure 780. Here, the first electrode structure 770 may be exposed.

Subsequently, a fourth interlayer insulating layer IL4 may be formed on the source structure SS. Subsequently, a third interconnection structure IC3 may be formed. The third interconnection structure IC3 may include third vias ICE and third lines ICF. The third interconnection structure IC3 may be connected to at least one of the source structure SS or the first electrode structure 770. For example, at least one of the third vias ICE may be connected to at least one of the source structure SS or the first electrode structure 770.

According to the manufacturing method described above, the peripheral circuit wafer PWF including the first bonding pads BP1 and the cell wafer CWF including the second bonding pads BP2 may be formed. Subsequently, the peripheral circuit wafer PWF and the cell wafer CWF may be electrically connected by bonding the first bonding pads BP1 and the second bonding pads BP2.

In addition, a capacitor may be formed on the peripheral circuit PC of the peripheral circuit wafer PWF, and the first electrode structure 770, the electrode layers, the second electrode structure 780, and the insulating spacer 790 may be used as the capacitor CS on the cell wafer CWF. Therefore, the capacitor CS may be formed in a region other than the peripheral circuit PC in a limited area.

Although embodiments according to the technical spirit of the present disclosure have been described with reference to the accompanying drawings, this is only for describing an embodiment according to the concept of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
a substrate including a cell region and a peripheral circuit region;
a gate structure including conductive layers and being located in the cell region;
an electrode stack including electrode layers and being located in the peripheral circuit region;
a slit structure extending through the gate structure;
first electrode structures extending through the electrode stack and being electrically connected to the electrode layers;
a second electrode structure extending through the electrode stack and being located at a level corresponding to the slit structure;
and
an insulating spacer surrounding the second electrode structure.

2. The semiconductor device of claim 1, wherein the first electrode structures, the electrode layers, the second electrode structure, and the insulating spacer are configured as a capacitor.

3. The semiconductor device of claim 1, further comprising:
a peripheral circuit located on the substrate;
a source structure located on the peripheral circuit;
channel structures extending into the source structure through the gate structure; and
first contact vias connected to the conductive layers, respectively.

4. The semiconductor device of claim 3, wherein the second electrode structure extends into the source structure through the electrode stack.

5. The semiconductor device of claim 4, wherein the source structure is located between the peripheral circuit and the gate structure and between the peripheral circuit and the electrode stack.

6. The semiconductor device of claim 4, wherein the source structure is located on the gate structure and the electrode stack.

7. The semiconductor device of claim 6, further comprising a bonding structure located between the peripheral circuit and the gate structure and between the peripheral circuit and the electrode stack.

8. The semiconductor device of claim 3, further comprising second contact vias connected to the slit structure and the second electrode structure, respectively.

9. The semiconductor device of claim 1,
wherein each of the slit structure and the second electrode structure has a line shape extending in a first direction, and
wherein the first electrode structures have a plug shape.

10. The semiconductor device of claim 1, further comprising a residual stack located in the peripheral circuit region and located at a level corresponding to the electrode stack.

11. The semiconductor device of claim 10, further comprising:
first supports extending through the electrode stack and being arranged in a first direction and a second direction intersecting with the first direction; and
second supports extending in the second direction and being located between the electrode stack and the residual stack.

12. The semiconductor device of claim 1, wherein the first electrode structures and the second electrode structure include different materials.

13. The semiconductor device of claim 12,
wherein the first electrode structures include tungsten, and
wherein the second electrode structure includes polysilicon.

14. A semiconductor device comprising:
an electrode stack including electrode layers;
a first electrode structure extending through the electrode stack and being electrically connected to the electrode layers;
a second electrode structure extending through the electrode stack and including a material different from a material of the first electrode structure; and
an insulating spacer surrounding the second electrode structure.

15. The semiconductor device of claim 14, wherein the first electrode structure, the electrode layers, the second electrode structure,
and the insulating spacer are configured as a capacitor.

16. The semiconductor device of claim 14, further comprising:
a substrate including a cell region and a peripheral circuit region;
a gate structure located in the cell region and located at a level corresponding to the electrode stack;
a slit structure extending through the gate structure; and channel structures extending through the gate structure.

17. The semiconductor device of claim 16, wherein the second electrode structure is located at a level corresponding to the slit
structure.

18. The semiconductor device of claim 16, further comprising:
a peripheral circuit located on the substrate; and
a source structure located on the peripheral circuit.

19. The semiconductor device of claim 18, wherein the second electrode structure extends into the source structure through the electrode stack.

20. The semiconductor device of claim 19, wherein the source structure is located between the peripheral circuit and the gate structure and between the peripheral circuit and the electrode stack.

21. The semiconductor device of claim 19, wherein the source structure is located on the gate structure and the electrode stack.

22. The semiconductor device of claim 21, further comprising a bonding structure located between the peripheral circuit and the gate
structure and between the peripheral circuit and the electrode stack.

23. The semiconductor device of claim 16,
wherein each of the slit structure and the second electrode structure has a line shape extending in a first direction, and
wherein the first electrode structure has a plug shape.

24. The semiconductor device of claim 14, further comprising a cell stack located at a level corresponding to the electrode stack.

25. The semiconductor device of claim 24, further comprising:
first supports extending through the electrode stack and being arranged in a first direction and a second direction intersecting with the
first direction; and
second supports extending in the second direction and being located between the electrode stack and the cell stack.

26. The semiconductor device of claim 14,
wherein the first electrode structure includes tungsten, and
wherein the second electrode structure includes polysilicon.
